(19) United States
(12) Patent Application Publication
(10) Pub. No.: US 2026/0282709 A1
(43) Pub. Date: Sep. 17, 2026

(54) WINDOW, DISPLAY DEVICE INCLUDING THE SAME, AND ELECTRONIC DEVICE INCLUDING THE DISPLAY DEVICE

(71) Applicant: Samsung Display Co., LTD., Yongin-si (KR)

(72) Inventors: BEOMSOO KIM, Yongin-si (KR); SEUNGJUN LEE, Yongin-si (KR)

(21) Appl. No.: 19/464,990

(22) Filed: Jan. 30, 2026

(30) Foreign Application Priority Data
Mar. 11, 2025 (KR) 10-2025-0031102

(51) Int. Cl. H10K 59/80; H10K 102/00

(52) U.S. Cl. CPC H10K 59/873; H10K 2102/311

(57) ABSTRACT

A window includes a folding area including a first-first portion that is foldable with respect to a folding axis extending in a first direction and has a uniform thickness and a non-folding area defined next (adjacent) to the folding area in a second direction perpendicular to the first direction in an unfolded state of the window and including a second-first portion having a thickness that increases as a distance from the first-first portion increases.

### CROSS-REFERENCE TO RELATED APPLICATION

This application claims priority to Korean Patent Application No. 10-2025-0031102, filed on Mar. 11, 2025, and all the benefits accruing therefrom under 35 U.S.C. §119, the content of which in its entirety is herein incorporated by reference.

### BACKGROUND

### Field

The disclosure relates to a window, a display device including the same, and an electronic device including the display device. More particularly, the disclosure relates to a window including a wide slant portion, a display device including the window, and an electronic device including the display device.

### Description of Related Art

Electronic devices display images to provide information to users. Recently, various types of electronic devices are being developed. In particular, foldable electronic devices are being developed.

An electronic device includes a display device and a window. The window includes a glass substrate. Window structures are being developed to improve the impact resistance and strength of the window providing an outer surface of the electronic device and to reduce the stress generated during folding.

### SUMMARY

The disclosure provides a window with improved impact resistance for a display device.

The disclosure provides a display device including the window.

The disclosure provides an electronic device including the window.

An embodiment of the inventive concept provides a window including a folding area including a first-first portion that is foldable with respect to a folding axis extending in a first direction and has a uniform thickness and a non-folding area defined next (adjacent) to the folding area in a second direction perpendicular to the first direction in an unfolded state of the window and including a second-first portion having a thickness that increases as a distance from the first-first portion increases.

In an embodiment, the folding area further includes a first-second portion disposed between the first-first portion and the second-first portion, having a thickness that increases as a distance from the first-first portion increases, including an upper surface connected to an upper surface of the first-first portion and an upper surface of the second-first portion.

In an embodiment, the first-first portion has a width of about 5 millimeters (mm) in the second direction.

In an embodiment, the thickness of the first-first portion is about 30 micrometers.

In an embodiment, the non-folding area further includes a second-second portion disposed between the second-first portion and an edge of the glass substrate, including an upper surface connected to an upper surface of the second-first portion, and having a uniform thickness.

The second-second portion has a width of about 1 mm in the second direction.

The thickness of the second-second portion is in a range from about 100 micrometers to about 230 micrometers.

In an embodiment, one of an upper surface and a lower surface of the glass substrate is a flat surface, and the other one thereof (a remaining one of the upper surface and the lower surface of the glass substrate) is provided with a concave area defined therein.

In an embodiment, the window further includes a resin layer that overlaps the folding area and the non-folding area and includes an upper surface that is flat.

An embodiment of the inventive concept provides a display device including a display panel including a folding area that is foldable with respect to a folding axis extending in a first direction, a first non-folding area, and a second non-folding area facing the first non-folding area such that the folding area is disposed between the first non-folding area and the second non-folding area and a window coupled to the display panel and including a glass substrate. The glass substrate includes a concave area defined in the folding area, the first non-folding area, and the second non-folding area.

In an embodiment, a ratio of a length of the concave area to a length between a first edge and a second edge of the display device is about 90% or more in a second direction perpendicular to the first direction.

In an embodiment, the concave area includes a flat surface, a first slant surface, and a second slant surface, and the first slant surface faces the second slant surface such that the flat surface is disposed between the first slant surface and the second slant surface.

In an embodiment, the flat surface overlaps the folding area, and the first slant surface and the second slat surface overlap a portion of the folding area, the first non-folding area, and the second non-folding area.

In an embodiment, the window further includes a resin layer disposed on an upper surface of the glass substrate and filled in the concave area, and an upper surface of the resin layer is flat.

In an embodiment, the concave area has a depth in a range about 40 micrometers to about 200 micrometers.

An embodiment of the inventive concept provides an electronic device including a display panel including a folding display portion that is foldable with respect to a folding axis extending in a first direction, a first non-folding display portion, and a second non-folding display portion facing the first non-folding display portion such that the folding display portion is disposed between the first non-folding display portion and the second non-folding display portion and a window disposed on the display panel and including a glass substrate. The glass substrate includes a first portion overlapping a portion of the folding display portion and including a flat surface in one surface thereof and a second portion disposed in a portion of the folding display portion, the first non-folding display portion, and the second non-folding display portion and including a slant surface in one surface thereof.

In an embodiment, a distance between portions of an upper surface of the window, which face each other, is smaller than a distance between portions of an upper surface of the display panel, which face each other in a folded state of the display panel and the window.

In an embodiment, the electronic device further includes a cover layer. The flat surface of the first portion and the slant surface of the second portion are defined in an upper surface of the glass substrate, the cover layer is disposed on the glass substrate, a lower surface of the cover layer contacts the upper surface of the glass substrate, and an upper surface of the cover layer is flat.

In an embodiment, a distance between portions of an upper surface of the window, which face each other, is greater than a distance between portions of an upper surface of the display panel, which face each other in a folded state of the display panel and the window.

In an embodiment, the electronic device further includes a cover layer. The flat surface of the first portion and the slant surface of the second portion are defined in a lower surface of the glass substrate, an upper surface of the glass substrate is flat, the cover layer is disposed between the display panel and the glass substrate, and an upper surface of the cover layer contacts the lower surface of the glass substrate.

According to the above, a slope of the glass substrate is reduced by extending a slant portion of the glass substrate of the window to the non-folding area. As the slope of the slant portion is reduced, a compressive stress applied to the slant portion is lowered, and thus, a buckling phenomenon is reduced. Since the slope becomes gentler, impact applied to the slant portion is distributed and impact resistance is enhanced. As the slope is reduced, the difference in the degree of light reflection between the flat surface and the slant surface decreases, and thus, it is possible to prevent the slant surface from being visible when the window is viewed from above.

### BRIEF DESCRIPTION OF THE DRAWINGS

The above and other embodiments, advantages and features of this disclosure will become more apparent by describing in further detail embodiments thereof with reference to the accompanying drawings, in which:

FIG. 1 is a block diagram of an embodiment of an electronic device of the disclosure;

FIG. 2 is a schematic view of embodiments of electronic devices of the disclosure;

FIGS. 3A-3C are perspective views of an embodiment of an electronic device of the disclosure;

FIG. 4 is an exploded perspective view of an embodiment of an electronic device of the disclosure;

FIG. 5A is a cross-sectional view of an embodiment of a display device in a folded state of the disclosure;

FIG. 5B is a cross-sectional view of an embodiment of a display device of the disclosure;

FIG. 6 is a cross-sectional view of an embodiment of a window of the disclosure;

FIG. 7 is a cross-sectional view of an embodiment of a window of the disclosure;

FIG. 8A is a cross-sectional view of an embodiment of a display device in a folded state of the disclosure; and

FIG. 8B is a cross-sectional view of an embodiment of a display device of the disclosure.

### DETAILED DESCRIPTION

In the disclosure, it will be understood that when an element (or area, layer, or portion) is referred to as being "on", "connected to" or "coupled to" another element or layer, it may be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure. As used herein, the singular forms, “a”, “an” and “the” are intended to include the plural forms as well, unless the context clearly indicates otherwise.

Spatially relative terms, such as “below”, “lower”, “above”, “upper” and the like, may be used herein for ease of description to describe one element or feature's relationship to another elements or features as shown in the drawing figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

"About" or "approximately" as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term "about" can mean within one or more standard deviations, or within ± 30%, 20%, 10%, 5% of the stated value, for example.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described with reference to accompanying drawings.

A display device according to the disclosure may be applied to various electronic devices. The electronic device according to the disclosure includes the display device and may further include modules or devices having additional functions in addition to the display device.

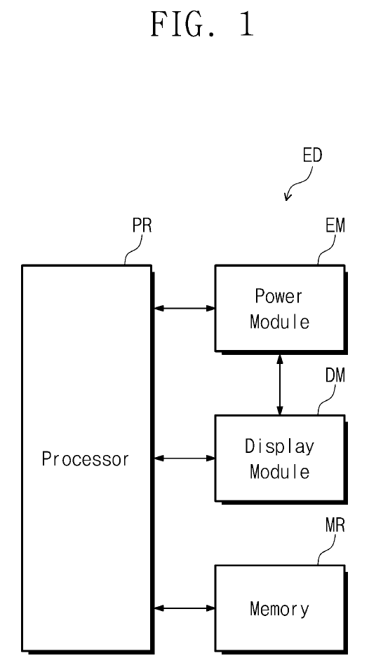

FIG. 1 is a block diagram of an embodiment of the electronic device of the disclosure. Referring to FIG. 1, the electronic device ED may include a display module DM, a processor PR, a memory MR, and a power module EM.

The processor PR may include at least one of a central processing unit (“CPU”), an application processor (“AP”), a graphics processing unit (“GPU”), a communication processor (“CP”), an image signal processor (“ISP”), and a controller.

The memory MR may store data information desired for the operation of the processor PR or the display module DM. When the processor PR executes an application stored in the memory MR, an image data signal and/or an input control signal may be transmitted to the display module DM, and the display module DM may process the received signals to output image information through a display screen.

The power module EM may include a power supply module, such as a power adapter or a battery device, and a power conversion module that converts power supplied by the power supply module to generate power desired for the operation of the electronic device ED.

At least one of components of the electronic device ED may be included in display devices. In addition, among individual modules that are functionally included within a single module, some may be included in the display device while others may be provided separately from the display device. In an embodiment, the display device may include the display module DM, and the processor PR, the memory MR, and the power module EM may be provided as separate devices within the electronic device ED without being included in the display device.

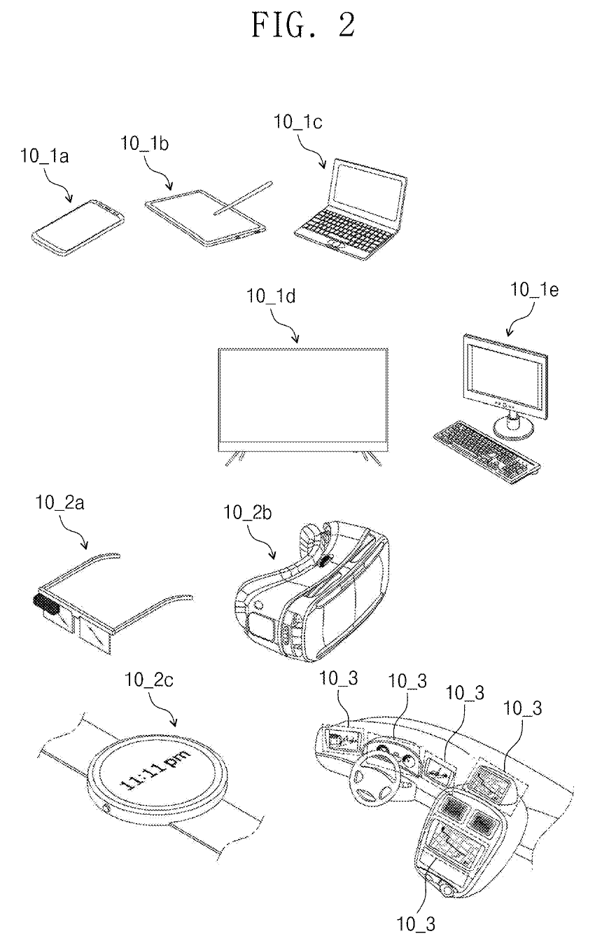

FIG. 2 is a schematic view of embodiments of various electronic devices of the disclosure.

Referring to FIG. 2, various electronic devices to which display devices in embodiments are applied may include an electronic device to display images, such as a smartphone 10_1a, a tablet personal computer (“PC”) 10_1b, a laptop computer 10_1c, a television 10_1d, a desktop monitor 10_1e, etc., a wearable electronic device including a display module, such as a smart glasses 10_2a, a head-mounted display 10_2b, a smartwatch 10_2c, etc., or an in-vehicle electronic device 10_3 including a display module, such as an instrument panel, a center fascia, a dashboard-mounted center information display (“CID”), or a room mirror display.

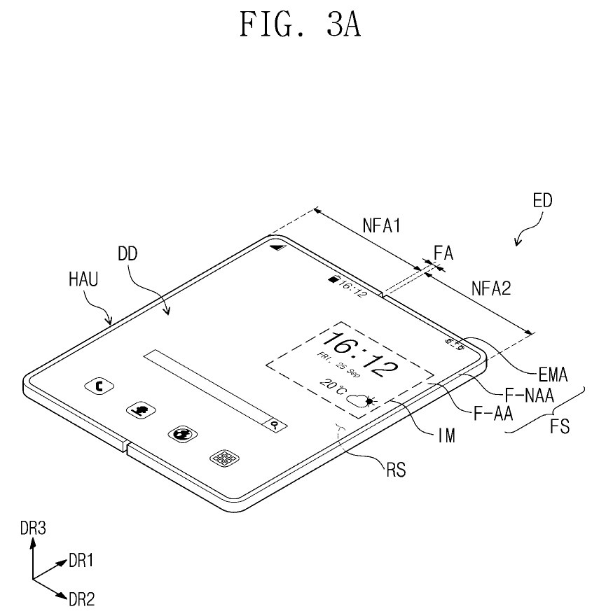

FIGS. 3A-3C are perspective views of an embodiment of an electronic device of the disclosure.

Referring to FIGS. 3A-3C, the electronic device ED may include a display device DD and a housing HAU accommodating the display device DD. The electronic device ED may include a display surface FS provided by the display device DD and a rear surface RS opposite to the display surface FS. The display surface FS may be defined by a first direction DR1 and a second direction DR2 intersecting the first direction DR1. The electronic device ED may provide an image IM to a user through the display surface FS. The image IM may be provided toward a third direction DR3. However, the disclosure is not limited thereto, and in another embodiment, the rear surface RS may also display an image which is the same as or different from the image IM. Hereinafter, a direction substantially perpendicular to a plane defined by the first direction DR1 and the second direction DR2 is defined as a third direction DR3. In addition, in this specification, the expression "in a plan view" may be defined as a state viewed from the third direction DR3.

The display surface FS of the electronic device ED may include a display area F-AA and a peripheral area F-NAA. The image IM may be displayed through the display area F-AA. The peripheral area F-NAA may be defined next (adjacent) to the display area F-AA. The peripheral area F-NAA may not display the image IM and may have a selected color. The peripheral area F-NAA may surround the display area F-AA, however, it should not be limited thereto or thereby. In an embodiment, the peripheral area F-NAA may be defined next (adjacent) to only one side of the display area F-AA or may be omitted. In an embodiment, the electronic device ED may include a display area of various shapes, and it should not be particularly limited.

The display surface FS may further include a sensing area EMA. Various electronic modules may be arranged in the sensing area EMA. In an embodiment, the electronic module may include at least one of a camera module, an optical sensor, and a thermal sensor. The sensing area EMA may be surrounded by the display area F-AA. In the illustrated embodiment, one sensing area EMA is shown as an illustrative embodiment, but the number of the sensing areas EMA should not be limited thereto or thereby.

The sensing area EMA may be a portion of the display area F-AA. Accordingly, the image IM may be displayed through the sensing area EMA. In an embodiment, when the electronic modules arranged in the sensing area EMA are deactivated, the sensing area EMA may serve as the portion of the display area F-AA to display the image IM, for example.

The display surface FS may include a folding area FA and non-folding areas NFA1 and NFA2. The electronic device ED may include a plurality of non-folding areas NFA1 and NFA2. In the illustrated embodiment, the electronic device ED may include first and second non-folding areas NFA1 and NFA2, and the folding area FA may be disposed between the first and second non-folding areas NFA1 and NFA2. FIGS. 3A-3C show the electronic device ED including one folding area FA, however, the disclosure should not be limited thereto or thereby. In an embodiment, the electronic device ED may include a plurality of folding areas.

Referring to FIGS. 3B and 3C, the electronic device ED may be folded with respect to a folding axis FX extending in one direction. The folding axis FX shown in FIGS. 3B and 3C may be an imaginary axis that extends in the first direction DR1, is defined to overlap the folding area FA, and is substantially parallel to a direction in which a long side of the electronic device ED extends.

Referring to FIG. 3B, the electronic device ED may be folded to allow the first non-folding area NFA1 and the second non-folding area NFA2 to face each other. That is, the electronic device ED may be inwardly folded, and thus, the display surface FS may not be exposed to the outside. Referring to FIG. 3C, the electronic device ED may be outwardly folded to allow the display surface FS to be exposed to the outside.

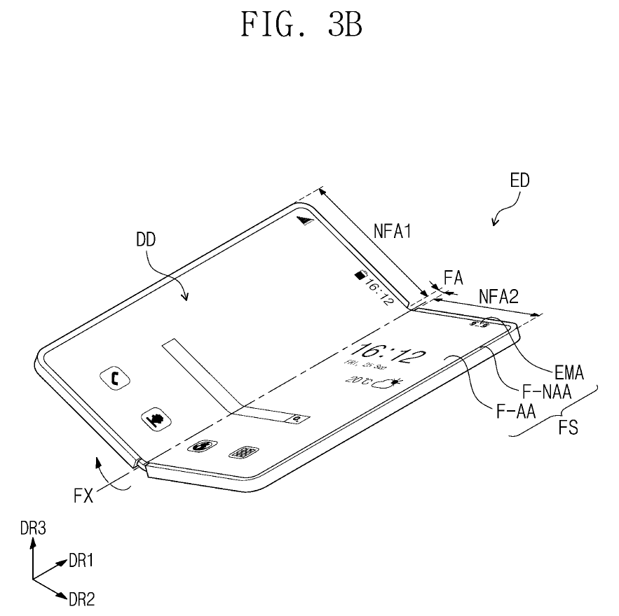

FIG. 4 is an exploded perspective view of an embodiment of the electronic device ED of the disclosure.

The electronic device ED may include a display panel DP and a window WM disposed on the display panel DP. The display panel DP and the window WM may be accommodated in the housing HAU.

The display panel DP may be a light-emitting type display panel. In an embodiment, the display panel DP may be an organic light-emitting display panel, an inorganic light-emitting display panel, a micro-light-emitting diode (“micro-LED”) display panel, a micro-organic LED (“micro-OLED”) display panel, or a nano-LED display panel, for example.

The display panel DP may include a display area DP-DA and a non-display area DP-NDA. The display area DP-DA may be an area in which pixels are arranged and may generate the image IM described with reference to FIGS. 3A-3C. The display area DP-DA of the display panel DP may correspond to the display area F-AA described with reference to FIGS. 3A-3C. The non-display area DP-NDA may correspond to the peripheral area F-NAA described with reference to FIGS. 3A-3C. In the disclosure, the expression “an area (or a portion) corresponds to another area (or another portion)” means that “an area (or a portion) overlaps another area (or another portion)”, however, they should not be limited to having the same size or the same shape as each other.

The display panel DP may include a folding area FA-D (or a folding display portion), a first non-folding areas (or a first non-folding display portion) NFA1-D and a second non-folding areas (or a second non-folding display portion) NFA2-D, which correspond to the folding area FA, the first non-folding areas NFA1, and the second non-folding areas NFA2 of the electronic device ED (or the display device DD) described with reference to FIGS. 3A-3C. In FIG. 4, a portion of the second non-folding area NFA2-D, which protrudes more than the window WM, may be bent and disposed under the second non-folding area NFA2-D.

The electronic device ED may include a window adhesive layer AP-W disposed between the display panel DP and the window WM. The window adhesive layer AP-W may be an optically clear adhesive (“OCA”) film or an optically clear adhesive resin (“OCR”) layer. In an embodiment, the window adhesive layer AP-W may be omitted.

The window WM may provide the display surface FS described with reference to FIGS. 3A-3C. That is, the window WM may provide a front surface of the electronic device ED. The window WM may include a folding area FA-W and first and second non-folding areas NFA1-W and NFA2-W, which correspond to the folding area FA and the first and second non-folding areas NFA1 and NFA2 of the electronic device ED. The folding area FA-W may be bent at a selected curvature when the electronic device ED is folded.

Although not shown separately, the window WM may include a base substrate and a bezel pattern arranged on one surface of the base substrate. An area where the bezel pattern is disposed may define the peripheral area F-NAA described with reference to FIGS. 3A-3C. In an embodiment, the bezel pattern may be omitted.

In an embodiment, the electronic device ED may further include an input sensor module on the display panel DP, for example. The display panel DP or a module including the display panel DP and the input sensor module may be also referred to as the display module DM (refer to FIG. 1). The electronic device ED may further include a lower module disposed under the display panel DP. The lower module may further include at least one of a support module, a protective layer, and a buffer layer. The electronic device ED may further include a protective film and a protective adhesive layer, which are disposed on the window WM. The electronic module, for instance, the processor PR, the memory MR, and the power module EM described with reference to FIG. 1, may be arranged in a space defined by the display panel DP and the housing HAU. In addition, other components described with reference to FIGS. 3A-3C may also be arranged in the space.

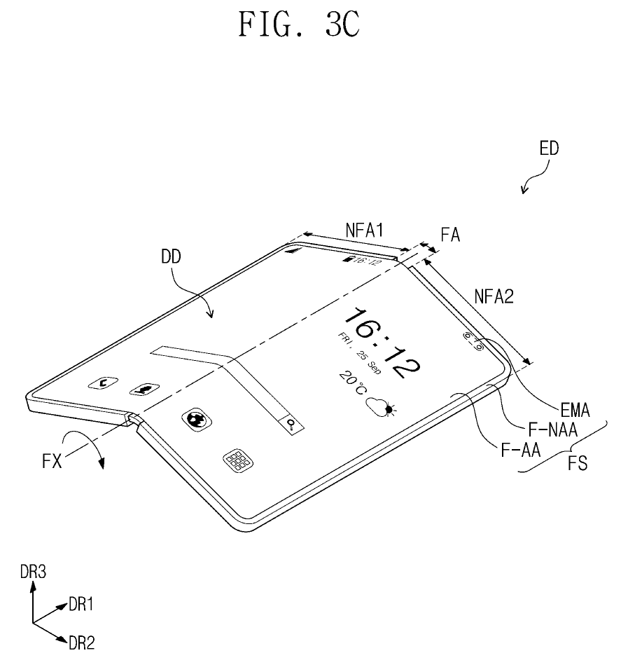

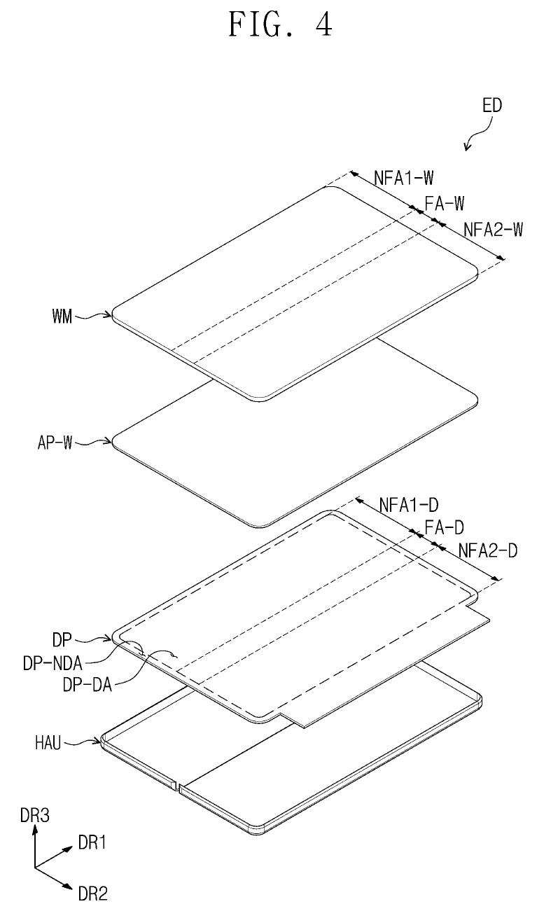

FIG. 5A is a cross-sectional view of an embodiment of the display device in a folded state of the disclosure. FIG. 5B is a cross-sectional view of an embodiment of the display device in an unfolded state of the disclosure.

For the convenience of explanation, FIG. 5A shows only the display panel DP, the window adhesive layer AP-W, and the window WM among components included in the display device DD, and other components are omitted.

FIG. 5A shows a cross-section of the display device in an inwardly-folded state, with reference to a folding axis FX1, where a distance D_{WM} between portions of an upper surface of the window WM, which face each other, is smaller than a distance D_{DM} between portions of an upper surface of the display panel DP, which face each other, when the display device DD is folded.

FIG. 5B is a cross-section of the display device DD, which operates in the inwardly-folded state of FIG. 5A, in the unfolded state. Referring to FIG. 5B, the window WM may include a glass substrate GS and a resin layer RL disposed on one surface of the glass substrate GS.

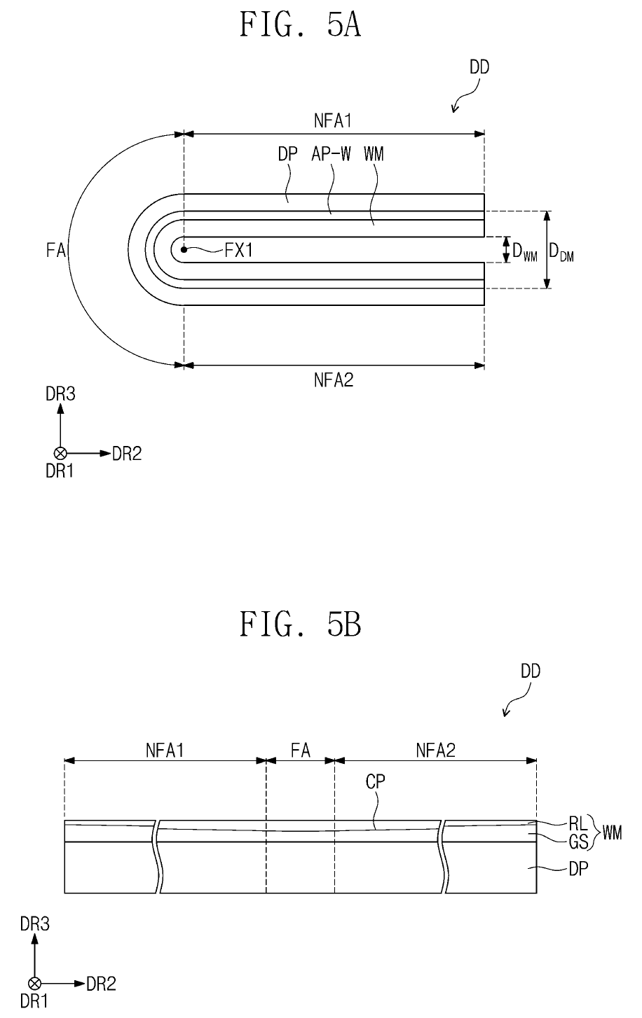

Referring to FIG. 5B, the glass substrate GS may include a concave area CP that is concave upward with respect to the display surface FS of FIGS. 3A-3C. The concave area CP may be defined in the folding area FA and the non-folding areas NFA1 and NFA2. The concave area may cover an entirety of the non-folding areas NFA1 and NFA2. The structure of the glass substrate GS will be described in detail with reference to FIG. 6.

The resin layer RL may be provided on the glass substrate GS to fill the concave area. The resin layer RL may cover the top surface of the glass substrate GS and may be defined as a cover layer. The resin layer RL may include an acrylic resin, an epoxy resin, a silicone resin, a urethane resin, a urethane acrylate resin, a hybrid sol-gel, and a siloxane-based resin. The window WM having the above-described structure may maintain the optical and design characteristics of the glass substrate GS while providing enhanced impact resistance through the resin layer RL. The display surface FS of FIGS. 3A-3C may be provided by an upper surface of the resin layer RL.

FIG. 6 is a cross-sectional view of an embodiment of the window of the disclosure.

The window WM may include the folding area FA-W and the non-folding areas NFA1-W and NFA2-W. The folding area FA-W may be folded with respect to the folding axis extending in the first direction DR1, and the non-folding areas NFA1-W and NFA2-W may be next (adjacent) to the folding area in the second direction DR2 when the window is in the unfolded state.

The glass substrate GS may include a first portion P1 corresponding to (or overlapping) the folding area FA-W and a second portion P2 corresponding to (or overlapping) the non-folding areas NFA1-W and NFA2-W.

The first portion P1 and the second portion P2 may be divided into multiple areas based on variations in thickness. The first portion P1 may include a first-first portion P1-1 having a substantially uniform thickness and a first-second portion P1-2 having a thickness that increases as a distance from the first-first portion P1-1 increases. The first-second portion P1-2 may be disposed between the first-first portion P1-1 and the second portion P2 and may connect the first-first portion P1-1 and the second portion P2.

The second portion P2 may include a second-first portion P2-1 having a thickness that increases as a distance from the first-second portion P1-2 increases and a second-second portion P2-2 having a substantially uniform thickness. The second-first portion P2-1 may be disposed between the first-second portion P1-2 and the second-second portion P2-2 and may connect the first-second portion P1-2 and the second-second portion P2-2. The second-second portion P2-2 may be disposed between the second-first portion P2-1 and edges EG1 and EG2 of the glass substrate GS.

The first portion P1 may have a thickness smaller than that of the second portion P2. The first-first portion P1-1 may have a relatively small thickness T2 to reduce a compressive stress when the window WM is folded. The expression “the first portion P1 has the smaller thickness than the second portion P2” may be the result of a comparison of thickness values measured at arbitrary measurement points of the first portion P1 and the second portion P2, or the result of a comparison of average thicknesses of the first portion P1 and the second portion P2. In an alternative embodiment, the expression may be the result of a comparison between a maximum thickness of the first portion P1 and a minimum thickness of the second portion P2. However, a boundary between the first portion P1 and the second portion P2 may be excluded when comparing the thicknesses of the two portions.

The thickness of the first-first portion P1-1 may be the same as the thickness of the first-second portion P1-2 at the boundary (or a boundary point ) between the first-first portion P1-1 and the first-second portion P1-2, and the thickness of the first-second portion P1-2 may be the same as the thickness of the second-first portion P2-1 at the boundary (or a boundary point) between the first-second portion P1-2 and the second-first portion P2-1.

The first-second portion P1-2 and the second-first portion P2-1 may constitute an integrally formed (or unitary) inclined region, and the first-second portion P1-2 and the second-first portion P2-1 may connect the first-first portion P1-1 and the edge EG of the glass substrate GS. The inclined region may be defined over the folding area FA-W and the non-folding areas NFA1-W and NFA2-W.

A portion of the second-second portion P2-2, which is next (adjacent) to the edge EG of the glass substrate GS, may have a uniform thickness, and thus, the impact resistance of the edge EG of the glass substrate GS, which is relatively vulnerable to external impacts, may be improved. In FIG. 6, the second-second portion P2-2 is shown, but the disclosure is not limited thereto, and the second-second portion P2-2 may be omitted in another embodiment.

The thickness T2 of the first-first portion P1-1 may be about 30 micrometers, and a thickness T1 of the second-second portion P2-2 may be within a range from about 100 micrometers to about 230 micrometers. In a case where the second-second portion P2-2 is omitted, the thickest portion of the second-first portion P2-1 may have a thickness within a range from about 100 micrometers to about 230 micrometers.

The glass substrate GS may be divided into multiple areas based on a slope of an upper surface thereof. The upper surface of the glass substrate GS may include a first flat surface FS1, a slant surface SS, and a second flat surface FS2. The slant surface SS may include a first slant surface SS1 overlapping the folding area FA-W and a second slant surface SS2 overlapping the non-folding areas NFA1-W and NFA2-W.

The first flat surface FS1, the first slant surface SS1, the second slant surface SS2, and the second flat surface FS2 may correspond to the first-first portion P1-1, the first-second portion P1-2, the second-first portion P2-1, and the second-second portion P2-2, respectively.

Two slant surfaces SS may be provided on opposite sides of the folding area FA-W and may define the concave area CP while facing each other with the first flat surface FS1 disposed between the two slant surfaces SS. The concave area CP may be defined in the folding area FA-W, the first non-folding area NFA1-W, and the second non-folding area NFA2-W.

The glass substrate GS may have a length L1 determined by the electronic device ED (refer to FIG. 3A). The length L1 of the glass substrate GS may be determined by a length between a first edge EG1 and a second edge EG2. The first flat surface FS1 may have a length L2 greater than or equal to about 5 mm in the second direction DR2. The length L4 of the first flat surface FS1 may be smaller than a length of the folding area FA-W. The second flat surface FS2 may have a length L3 smaller than or equal to about 1 mm in the second direction DR2. A length L4 of the concave area CP may be greater than or equal to about 90% of the length L1 of the glass substrate GS. In the case where the second-second portion P2-2 is not formed, length L4 of the concave area CP may be the same as the length L1 of the glass substrate GS. A depth of the concave area CP may be defined by a value obtained by subtracting the thickness T2 of the first-first portion from the thickness T1 of the second-second portion P2-2. The depth of the concave area CP may be within a range from about 40 micrometers to about 200 micrometers.

The resin layer RL may be filled in the concave area CP to provide a flat upper surface. A portion of the glass substrate GS corresponding to the folding area FA-W may have a thickness greater than a thickness of portions of the glass substrate GS corresponding to the first non-folding area NFA1-W and the second non-folding area NFA2-W. Since the resin layer RL has the thickness that compensates for the thickness of the glass substrate GS, the window WM may have the uniform thickness in the folding area FA-W and the non-folding areas NFA1-W and NFA2-W.

According to the above-described structure, since the inclined region is defined not only in the folding area FA-W but also in the non-folding areas NFA1-W and NFA2-W, an angle defined by the slant surface SS with respect to the first flat surface FS1 may be reduced. The angle may be also referred to as a slope. When the slope is large, a difference in the degree of light reflection between the slant surface SS and the first flat surface FS1 may occur, and thus, the slant surface SS may become visible when the window WM is viewed from above. It is possible to prevent the slant surface SS from being visible by reducing the slope.

In addition, the reduction of the slope may disperse the compressive force generated during the folding of the electronic device, and thus, structural rigidity may be enhanced and a buckling phenomenon may be reduced. Further, when impact is applied to the window WM from outside, the impact may be spread out, and the impact resistance of the window WM may be improved.

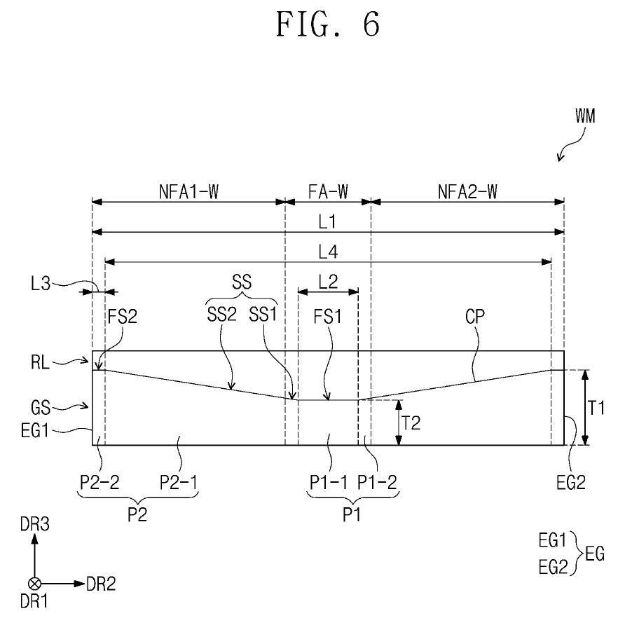

FIG. 7 is a cross-sectional view of an embodiment of a window WM’ of the disclosure.

In an embodiment, a first-second portion P1-2 and a second portion P2 that form a slant surface SS' of the window WM' may have a curved surface. The slope of the slant surface SS' with reference to a display surface FS’ may vary as a thickness of a glass substrate GS increases. When the slant surface SS' has the curved surface, the slope of the glass substrate GS may become gentler as it approaches an edge EG of the glass substrate GS. Since the window WM' may have sufficient impact resistance against external impacts even without an additional flat surface, the flat surface may be omitted. Non-folding areas NFA1-W and NFA2-W of the glass substrate GS may include only portions whose thickness increases as a distance from a folding area FA-W increases.

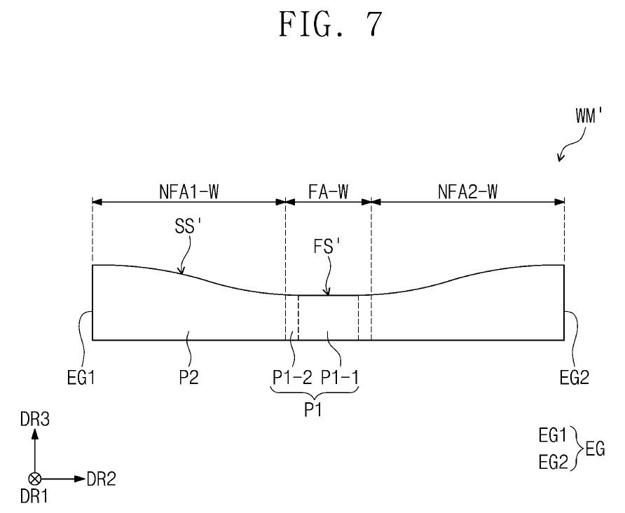

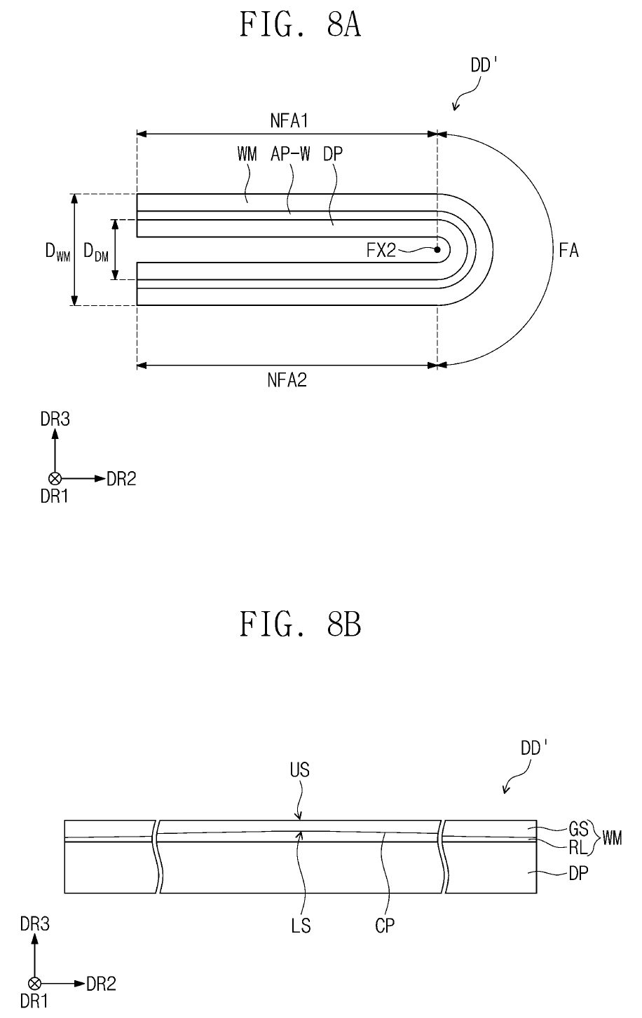

FIG. 8A is a cross-sectional view of an embodiment of a display device in a folded state of the disclosure. FIG. 8B is a cross-sectional view of an embodiment of a display device of the disclosure.

FIG. 8A schematically shows only a display panel DP, a window adhesive layer AP-W, and a window WM among components of a display device DD’. In FIGS. 8A and 8B, the similar/same reference numerals denote the similar/same elements in FIGS. 1-7, and thus, detailed descriptions of the similar/same elements will be omitted.

FIG. 8A illustrates a cross-section of the display device DD' in an outwardly-folded state, with reference to a folding axis FX2, and according to the display device DD', a distance D_{DM} between portions of an upper surface of the display panel DP, which face each other in the outwardly-folded state, is smaller than a distance D_{WM} between portions of an upper surface of the window WM, which face each other in the outwardly-folded state.

Referring to FIG. 8B, a display device DD' may include a resin layer RL disposed on the display panel DP and a glass substrate GS disposed on the resin layer RL. In FIG. 8B, the display surface FS of FIGS. 3A-3C may be provided by an upper surface of the glass substrate GS.

The upper surface US of the glass substrate GS may be a flat surface, and a concave area CP may be defined in a lower surface LS of the glass substrate GS. The window WM of the display device DD' that is outwardly folded may be obtained by arranging (or attaching) the upper surface of the window WM of FIG. 6 to face the display panel DP. The concave area CP of the glass substrate GS may be defined to face the display panel DP. FIG. 8B shows the window WM in which the positions of the glass substrate GS and the resin layer RL are reversed in comparison with the window WM shown in FIG. 5B.

In an embodiment, the stack structure of the window WM may be modified. In an embodiment, the resin layer RL may be omitted. In an embodiment, the resin layer RL may be replaced with an adhesive layer such as a pressure-sensitive adhesive sheet, for example. A protective film may further be disposed on the adhesive layer.

Although the embodiments of the disclosure have been described, it is understood that the disclosure should not be limited to these embodiments but various changes and modifications may be made by one ordinary skilled in the art within the spirit and scope of the disclosure as hereinafter claimed. Therefore, the disclosed subject matter should not be limited to any single embodiment described herein, and the scope of the inventive concept shall be determined according to the attached claims.

What is claimed is:

1. A window comprising:
a glass substrate comprising:
a folding area comprising:
a first-first portion which is foldable with respect to a folding axis extending in a first direction and has a uniform thickness; and
a non-folding area defined next to the folding area in a second direction perpendicular to the first direction in an unfolded state of the window is unfolded, the non-folding area comprising:
a second-first portion having a thickness which increases as a distance from the first-first portion increases.

2. The window of claim 1, wherein the folding area further comprises a first-second portion disposed between the first-first portion and the second-first portion, having a thickness which increases as a distance from the first-first portion increases, and comprising an upper surface connected to an upper surface of the first-first portion and an upper surface of the second-first portion.

3. The window of claim 1, wherein the first-first portion has a width of about 5 millimeters in the second direction.

4. The window of claim 1, wherein the thickness of the first-first portion is about 30 micrometers.

5. The window of claim 1, wherein the non-folding area further comprises a second-second portion disposed between the second-first portion and an edge of the glass substrate, comprising an upper surface connected to an upper surface of the second-first portion, and having a uniform thickness.

6. The window of claim 5, wherein the second-second portion has a width of about 1 millimeter in the second direction.

7. The window of claim 6, wherein the thickness of the second-second portion is in a range from about 100 micrometers to about 230 micrometers.

8. The window of claim 1, wherein one of an upper surface and a lower surface of the glass substrate is a flat surface, and a remaining one of the upper surface and the lower surface of the glass substrate is provided with a concave area defined in the glass substrate.

9. The window of claim 8, further comprising a resin layer which overlaps the folding area and the non-folding area and comprises an upper surface which is flat.

10. A display device comprising:
a display panel comprising:
a folding area which is foldable with respect to a folding axis extending in a first direction, a first non-folding area; and
a second non-folding area facing the first non-folding area so that the folding area is disposed between the first non-folding area and the second non-folding area; and
a window coupled to the display panel and comprising:
a glass substrate in which a concave area is defined in the folding area, the first non-folding area, and the second non-folding area.

11. The display device of claim 10, wherein a ratio of a length of the concave area to a length between a first edge and a second edge of the display device is about 90% or more in a second direction perpendicular to the first direction.

12. The display device of claim 10, wherein the concave area comprises a flat surface, a first slant surface, and a second slant surface, and the first slant surface faces the second slant surface so that the flat surface is disposed between the first slant surface and the second slant surface.

13. The display device of claim 12, wherein the flat surface overlaps the folding area, and the first slant surface and the second slat surface overlap a portion of the folding area, the first non-folding area, and the second non-folding area.

14. The display device of claim 10, wherein the window further comprises a resin layer disposed on an upper surface of the glass substrate and filled in the concave area, and an upper surface of the resin layer is flat.

15. The display device of claim 10, wherein the concave area has a depth in a range about 40 micrometers to about 200 micrometers.

16. An electronic device comprising:
a display device comprising:
a display panel comprising: a folding display portion which is foldable with respect to a folding axis extending in a first direction, a first non-folding display portion, and a second non-folding display portion facing the first non-folding display portion so that the folding display portion is disposed between the first non-folding display portion and the second non-folding display portion; and
a window disposed on the display panel, the window comprising:
a glass substrate comprising:
a first portion overlapping a portion of the folding display portion, the first portion comprising:
a flat surface; and
a second portion disposed in a portion of the folding display portion, the first non-folding display portion, and the second non-folding display portion, the second portion comprising:
a slant surface; and
a processor which controls the display device.

17. The electronic device of claim 16, wherein a distance between portions of an upper surface of the window, which face each other, is smaller than a distance between portions of an upper surface of the display panel, which face each other in a folded state of the display panel and the window.

18. The electronic device of claim 17, further comprising a cover layer, wherein the flat surface of the first portion and the slant surface of the second portion are defined in an upper surface of the glass substrate, the cover layer is disposed on the glass substrate, a lower surface of the cover layer contacts the upper surface of the glass substrate, and an upper surface of the cover layer is flat.

19. The electronic device of claim 16, wherein a distance between portions of an upper surface of the window, which face each other, is greater than a distance between portions of an upper surface of the display panel, which face each other in a folded state of the display panel and the window.

20. The electronic device of claim 19, further comprising a cover layer, wherein the flat surface of the first portion and the slant surface of the second portion are defined in a lower surface of the glass substrate, an upper surface of the glass substrate is flat, the cover layer is disposed between the display panel and the glass substrate, and an upper surface of the cover layer contacts the lower surface of the glass substrate.
